(19) United States
(12) Patent Application Publication
(10) Pub. No.: US 2018/0366262 A1
(43) Pub. Date: Dec. 20, 2018

(54) METHOD OF MANUFACTURING MAGNETIC SHIELDING BLOCK FOR WIRELESS POWER CHARGING, AND MAGNETIC SHIELDING BLOCK AND WIRELESS POWER RECEIVING DEVICE USING SAME

(71) Applicant: LG INNOTEK CO., LTD., Seoul (KR)

(72) Inventors: Dong Hyuk LEE, Seoul (KR); Hyoung Rae KIM, Seoul (KR); Ji Yeon SONG, Seoul (KR); Hye Min LEE, Seoul (KR)

(73) Assignee: LG INNOTEK CO., LTD., Seoul (KR)

(21) Appl. No.: 16/063,554

(22) PCT Filed: Nov. 2, 2016
(86) PCT No.: PCT/KR2016/012497

§ 371 Date: Jun. 18, 2018

(30) Foreign Application Priority Data
Dec. 28, 2015 (KR) 10-2015-0187494

(51) Int. Cl. H01F 27/36; H02J 50/10; H01F 27/28; H05K 9/00; H02J 7/02

(52) U.S. Cl. CPC H01F 27/36; H02J 50/10; H02J 7/025; H01F 27/2823; H05K 9/0075; H01F 27/2804

(57) ABSTRACT

The present invention relates to a magnetic shielding block for a wireless power receiver, and a method of manufacturing same. A method of manufacturing a magnetic shielding block according to an embodiment of the present invention may comprise the steps of: disposing a non-conductive magnetic shielding sheet between a first and second cover tape and laminating same; marking a cutting region on one side of the laminated cover tape; and cutting the marked cutting region.

### TECHNICAL FIELD

Embodiments relate to a wireless power transmission technique, and more particularly, to a magnetic shielding block for a wireless power receiver with high magnetic shielding performance and high magnetic permeability and a method of manufacturing the same.

### BACKGROUND ART

Recently, as information and communication technology rapidly develops, a ubiquitous society based on information and communication technology is being formed.

To allow information communication devices to be connected anytime and anywhere, sensors equipped with a computer chip having a communication function should be installed in all facilities. Therefore, supply of power to these devices or sensors is a new challenge. In addition, as the kinds of portable devices such as Bluetooth handsets and music players like iPods, as well as mobile phones, rapidly increase in number, charging batteries thereof has required time and effort. As a way to address this issue, wireless power transmission technology has recently drawn attention.

Wireless power transmission (or wireless energy transfer) is a technology for wirelessly transmitting electric energy from a transmitter to a receiver based on the induction principle of a magnetic field. In the 1800s, electric motors or transformers based on electromagnetic induction began to be used. Thereafter, a method of transmitting electric energy by radiating electromagnetic waves, such as a radio wave, laser, a high frequency wave or a microwave, was tried. Electric toothbrushes and some common wireless shavers are charged through electromagnetic induction.

Wireless energy transmission techniques introduced up to now may be broadly divided into magnetic induction, electromagnetic resonance, and RF transmission employing a short wavelength radio frequency.

In the magnetic induction scheme, when two coils are arranged adjacent to each other and current is applied to one of the coils, a magnetic flux generated at this time generates electromotive force in the other coil. This technology is being rapidly commercialized mainly for small devices such as mobile phones. In the electromagnetic induction scheme, power of up to several hundred kilowatts (kW) may be transmitted with high efficiency, but the maximum transmission distance is less than or equal to 1 cm. As a result, devices are generally required to be placed adjacent to a charger or a pad, which is disadvantageous.

The magnetic resonance scheme uses an electric field or a magnetic field instead of employing an electromagnetic wave or current. The magnetic resonance scheme is advantageous in that the scheme is safe for other electronic devices or the human body since it is hardly influenced by electromagnetic waves. However, the distance and space available for this scheme are limited, and the energy transfer efficiency of the scheme is rather low.

The short-wavelength wireless power transmission scheme (simply, RF transmission scheme) takes advantage of the fact that energy can be transmitted and received directly in the form of radio waves. This technique is an RF-based wireless power transmission scheme using a rectenna. A rectenna, which is a compound word of antenna and rectifier, refers to a device that converts RF power directly into direct current (DC) power. That is, the RF scheme is a technique of converting AC radio waves into DC waves. Recently, with improvement in efficiency, commercialization of RF technology has been actively researched.

The wireless power transmission technique is employable in various industries including automobiles, IT, railroads, and home appliances as well as the mobile industry.

In general, a wireless power transmission device is provided with a coil for wireless power transmission (hereinafter referred to as a transmission coil), and employs various shielding members for blocking transmission of an electromagnetic field generated by the transmission coil or AC power to a control board.

Typical examples of shielding members are a magnetic shielding sheet and a sandust block obtained by processing a ferromagnetic metal powder.

A wireless power reception device also employs a magnetic shielding member for shielding an electromagnetic field received by a reception coil.

For a small wireless charging reception module currently mounted in a smart watch, however, it is difficult to increase the coefficient of coupling with the transmission coil due to the size of the module and thus the charging efficiency is 70% or less.

### DISCLOSURE

### Technical Problem

Therefore, the present disclosure has been made in view of the above problems, and embodiments provide a magnetic shielding block for a wireless power receiver and a method of manufacturing the same.

Embodiments provide a magnetic shielding block having high magnetic permeability as well as an insulation property for an AC component, and a method of manufacturing the same.

Embodiments provide a magnetic shielding block and a method of manufacturing the same for providing a wireless power receiver with a wireless power reception efficiency of 70% or more, and a method of manufacturing the same.

The technical objects that can be achieved through the embodiments are not limited to what has been particularly described hereinabove and other technical objects not described herein will be more clearly understood by persons skilled in the art from the following detailed description.

### Technical Solution

The present disclosure may provide a magnetic shielding block for a wireless power receiver and a method of manufacturing the same.

In one embodiment, a method of manufacturing a magnetic shielding block may include disposing a nonconductive magnetic shielding sheet between first and second cover tapes and bonding the same together, marking a cutting area on one surface of the bonded cover tapes, and cutting off the marked cutting area.

Here, the nonconductive magnetic shielding sheet may be formed of a ferrite-based material.

For example, the ferrite-based material may be any one of a Ni—Zn—Cu-based material, a Ni—Zn-based material and a Mn—Zn-based material.

In addition, the cutting area may be circular and a diameter of the cutting area may be less than or equal to 30 mm.

In addition, a magnetic permeability of the nonconductive magnetic shielding sheet may have a real part less than or equal to 300 and an imaginary part less than or equal to 20 in a low frequency band below 300 KHz.

In another embodiment, a method of manufacturing a magnetic shielding block may include producing a bonded block using first to n-th conductive magnetic shielding sheets and n-1 intermediate adhesive members, marking a cutting area on one surface of the bonded block, cutting off the marked cutting area, and insulating surfaces of the cut bonded block using a first insulating cover tape and a second insulating cover tape to be adhered to upper and lower surfaces of the cut bonded block, respectively.

Here, the insulating of the surfaces of the bonded block may include cutting the first insulating cover tape and the second insulating cover tape such that cut surfaces of the bonded block are all wrapped by the first insulating cover tape and the second insulating cover tape, adhering the cut first insulating cover tape and second insulating cover tape to centers of the upper and lower surfaces of the cut bonded block, and pressing edges of the adhered first insulating cover tape and second insulating cover tape toward the cut surfaces and adhering the edges to the cut surfaces.

In addition, the cutting of the first insulating cover tape and the second insulating cover tape may include calculating a cutting diameter based on a diameter of the upper surface and a value of n, and cutting off the first insulating cover tape and the second insulating cover tape based on the calculated diameter.

In addition, the conductive magnetic shielding sheets may be formed of any one of a nano-crystal-based material and an amorphous-based material.

In addition, the conductive magnetic shielding sheets may have a thickness of 17 micrometers (μm) to 25 μm.

In addition, the magnetic shielding block may be used in a wireless power receiver and have a diameter of 30 mm or less.

In another embodiment, a method of manufacturing a magnetic shielding block may include producing a bonded block using first to n-th conductive magnetic shielding sheets, n-1 intermediate adhesive members for adhering the first to n-th conductive magnetic shielding sheets to each other, and first and second insulating cover tapes to be attached to outermost conductive magnetic shielding sheets among the adhered first to n-th conductive magnetic shielding sheets, marking a cutting area on one surface of the bonded block, cutting off the marked cutting area, and applying an insulating coating agent to a cut surface of the cut bonded block.

In another embodiment, a wireless power reception device may include a reception coil configured to wirelessly receive alternating current (AC) power, a control circuit board connected to both terminals of the reception coil, a magnetic shielding member mounted between the reception coil and the control circuit board to block the received AC power from being transferred to the control circuit board, and an adhesive member configured to adhere the magnetic shielding member and the reception coil to each other.

Here, the reception coil may be any one of a patterned coil and a wire-wound coil.

In addition, the patterned coil may be mounted as the reception coil when a diameter of the reception coil exceeds 25 mm, and the wire-wound coil may be mounted as the reception coil when the diameter of the reception coil is greater than or equal 25 mm.

In addition, the magnetic shielding member may be a conductive magnetic shielding member formed of any one of a nano-crystal-based material and an amorphous-based material.

In addition, the magnetic shielding member may be a nonconductive magnetic shielding member formed of any one of a Ni—Zn—Cu-based material, a Ni—Zn-based material, and a Mn—Zn-based material.

Here, a magnetic permeability of the nonconductive magnetic shielding member may have a real part less than or equal to 300 and an imaginary part less than or equal to 20 in a low frequency band below 300 KHz.

In another embodiment, a magnetic shielding block may include first to n-th conductive magnetic shielding sheets, and n-1 intermediate adhesive members configured to adhering the first to n-th conductive magnetic shielding sheets to each other, wherein the first to the n-th conductive magnetic shielding sheets adhered to each other may be cut to a size of the reception coil and then subjected to surface insulation treatment.

Here, the surface insulation treatment may be performed using at least one of an insulating cover tape or an insulating coating agent.

In addition, the surface insulation treatment may be performed by applying the insulating coating agent to the cut surface.

The above-described aspects of the present disclosure are merely a part of preferred embodiments of the present disclosure. Those skilled in the art will derive and understand various embodiments reflecting the technical features of the present disclosure from the following detailed description of the present disclosure.

### Advantageous Effects

The method and device according to the embodiments have the following effects.

Embodiments provide a magnetic shielding block for a wireless power receiver and a method of manufacturing the same.

In addition, embodiments provide a magnetic shielding block having high magnetic permeability as well as an insulation property for an AC component, and a method of manufacturing the same.

Further, embodiments provide a magnetic shielding block and a method of manufacturing the same for providing a wireless power receiver with a wireless power reception efficiency of 70% or more, and a method of manufacturing the same.

It will be appreciated by those skilled in the art that that the effects that can be achieved through the embodiments of the present disclosure are not limited to those described above and other advantages of the present disclosure will be more clearly understood from the following detailed description

### DESCRIPTION OF DRAWINGS

The accompanying drawings, which are included to provide a further understanding of the disclosure, illustrate embodiments of the disclosure. It is to be understood, however, that the technical features of the present disclosure are not limited to specific drawings, and the features disclosed in the drawings may be combined to constitute new embodiments.

FIG. 1 is a view illustrating a schematic structure of a wireless power reception module according to an embodiment of the present disclosure.

FIG. 2 is a schematic process diagram illustrating a method of manufacturing a nonconductive magnetic shielding block according to an embodiment of the present disclosure.

FIG. 3 is a process diagram illustrating a method of manufacturing a conductive magnetic shielding block according to an embodiment of the present disclosure.

FIG. 4 is a process diagram illustrating a method of manufacturing a conductive magnetic shielding block according to another embodiment of the present disclosure.

FIG. 5 is a flowchart illustrating a method of manufacturing a nonconductive magnetic block according to an embodiment of the present disclosure.

FIG. 6 is a flowchart illustrating a method of manufacturing a conductive magnetic shielding block according to an embodiment of the present disclosure.

FIG. 7 is a flowchart illustrating a method of manufacturing a conductive magnetic shielding block according to another embodiment of the present disclosure.

FIG. 8 is a graph depicting wireless power reception efficiency of a wireless power reception module using a magnetic shielding block manufactured according to embodiments of the present disclosure.

### BEST MODE

The present disclosure relates to a magnetic shielding block for a wireless power receiver and a method of manufacturing the same. The method of manufacturing a magnetic shielding block according to an embodiment of the present disclosure may include arranging a nonconductive magnetic shielding sheet between first and second cover tapes and bonding the same, marking a cutting area on one surface of the bonded cover tapes, and cutting off the marked cutting area.

### Mode for Invention

Hereinafter, an apparatus and various methods to which embodiments of the present disclosure are applied will be described in detail with reference to the drawings. As used herein, the suffixes “module” and “unit” are added or interchangeably used to facilitate preparation of this specification and are not intended to suggest distinct meanings or functions.

In the description of the embodiments, it is to be understood that, when an element is described as being “on”/“over” or “beneath”/“under” another element, the two elements may directly contact each other or may be arranged with one or more intervening elements present therebetween. Also, the terms “on”/“over” or “beneath”/“under” may refer to not only an upward direction but also a downward direction with respect to one element.

For simplicity, in the description of the embodiments given below, “wireless power transmitter,” “wireless power transmission apparatus,” “transmission terminal,” “transmitter,” “transmission apparatus,” “transmission side,” “wireless power transfer apparatus,” “wireless power transferer,” and the like will be interchangeably used to refer to an apparatus for transmitting wireless power in a wireless power system. In addition, “wireless power reception apparatus,” “wireless power receiver,” “reception terminal,” “reception side,” “reception apparatus,” “receiver,” and the like will be used interchangeably to refer to an apparatus for wirelessly receiving power from a wireless power transmission apparatus.

The wireless power transmitter according to the present disclosure may be configured as a pad type, a cradle type, an access point (AP) type, a small base station type, a stand type, a ceiling embedded type, a wall-mounted type, a cup type, or the like. One transmitter may transmit power to a plurality of wireless power reception apparatuses. To this end, the wireless power transmitter may include at least one wireless power transmission means. Here, the wireless power transmission means may employ various wireless power transmission standards which are based on the electromagnetic induction scheme for charging according to the electromagnetic induction principle meaning that a magnetic field is generated in a power transmission terminal coil and current is induced in a reception terminal coil by the magnetic field. Here, the wireless power transmission means in the electromagnetic induction scheme may include wireless charging technology using electromagnetic induction schemes defined by the Wireless Power Consortium (WPC) and the Power Matters Alliance (PMA), which are wireless charging technology standard organizations.

A wireless power transmitter according to another embodiment of the present disclosure may employ various wireless power transmission standards which are based on the electromagnetic resonance scheme. For example, the electromagnetic power transmission standard in the electromagnetic resonance scheme may include wireless charging technology in the resonance scheme defined in A4WP (Alliance for Wireless Power).

A wireless power transmitter according to another embodiment of the present disclosure may support both the electromagnetic induction scheme and the electromagnetic resonance scheme.

In addition, a wireless power receiver according to an embodiment of the present disclosure may include at least one wireless power reception means, and may receive wireless power from two or more transmitters simultaneously. Here, the wireless power reception means may include wireless charging technologies of the electromagnetic induction schemes defined by the Wireless Power Consortium (WPC) and the Power Matters Alliance (PMA), which are wireless charging technology standard organizations, and the electromagnetic induction scheme defined by A4WP (Alliance for Wireless Power).

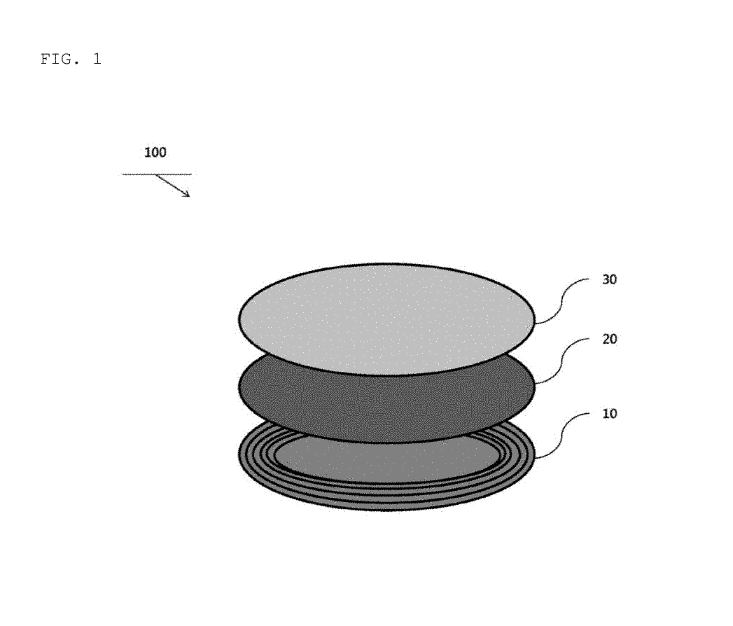

FIG. 1 is a view illustrating a schematic structure of a wireless power reception module according to an embodiment of the present disclosure.

Referring to FIG. 1, a wireless power reception module 100 may have a layered structure including a reception coil 10, an adhesive member 20, and a magnetic shielding member 30.

The reception coil 10 functions to receive a power signal transmitted through a transmission coil of a wireless power transmission apparatus. For example, the reception coil may be a patterned coil having a thin wiring pattern formed on a film or a thin printed circuit board, or a wire-wound coil formed by winding an insulator-coated coil, but this is merely an example. The configuration of the reception coil according to the embodiment of the present disclosure is not particularly limited, and any structure capable of receiving wireless power can be employed.

The reception coil 10 according to an embodiment of the present disclosure may be formed in the form of a wiring pattern on at least one surface of a coil substrate, and both ends of the reception coil may be electrically connected to a control circuit board (not shown). Here, the coil substrate may be, but is not limited to, an insulating substrate, a printed circuit board (PCB), a ceramic substrate, a pre-molded substrate, a DBC (direct bonded copper) substrate, or an insulated metal substrate (IMS). Any substrate having an insulating property is acceptable. Further, the coil substrate may be a resilient flexible substrate.

The adhesive member 20 adheres the reception coil 10 and the magnetic shielding member 30 to each other. It may be formed of a double-sided adhesive tape, but is not limited thereto. While the adhesive member 20 is illustrated in FIG. 1 as being attached to the whole one surface of the magnetic shielding member 30 and the reception coil 10, this is merely an embodiment. It may be formed so as to be attached to only a part of one surface of the magnetic shielding member 30 and the reception coil 10. For example, the adhesive member 20 may be in the shape of a circular ring, but is not limited thereto. It may have any shape that allows the reception coil 10 and the magnetic shielding member 30 to be adhered to each other.

While the adhesive member 20 is illustrated as taking the form of a double-sided adhesive sheet, this is merely an embodiment. According to another embodiment of the present disclosure, the adhesive member 20 may be an adhesive or an adhesive resin applied to one surface of the reception coil 10 or the magnetic shielding member 30.

The diameter of the reception coil 10 formed on the coil substrate according to an embodiment of the present disclosure may be 30 mm or less. If the diameter of the reception coil 10 is 25 mm or less, the reception coil 10 may be implemented with a wire-wound coil instead of a patterned coil. Generally, since the wire-wound coil has a lower resistance than the patterned coil, the wireless power reception efficiency thereof may be high. Generally, if the resistance of the reception coil 10 is high, the power loss resulting from heat generated by the resistance element may be high. Therefore, when the diameter of the reception coil 10 is reduced, using a wire-wound coil is preferable in minimizing the loss rate.

When the reception coil 10 according to an embodiment of the present disclosure is a wire-wound coil, the diameter of the wire of the wire-wound coil may range from 1.15 mm to 0.25 mm.

The magnetic shielding member 30 may be a ferrite-based nonconductive shielding member. For example, a Ni—Zn—Cu-based ferrite having a high permeability and a low loss of received power may be employed for the ferrite-based shielding member. Here, the magnetic permeability of the magnetic shielding member 30 to which the Ni—Zn—Cu-based ferrite is applied has a real part which is less than or equal to 300 ; and an imaginary part which is less than or equal to 20 in a low frequency band (below 300 kHz).

As a magnetic shielding member 30 according to another embodiment of the present disclosure, a Ni—Zn-based or Mn—Zn-based nonconductive shielding member may be used.

As a magnetic shielding member 30 according to another embodiment of the present disclosure, a nanocrystal-based or amorphous silicon (a-Si)-based conductive shielding member may be used.

In general, the nonconductive shielding member such as a ferrite-based shielding member has a high shielding efficiency for the imaginary part of an AC signal component received by the reception coil 10, while the nanocrystal-based conductive shielding member and the amorphous-based conductive shielding member have a high shielding efficiency for the real part of the AC signal component received by the reception coil 10.

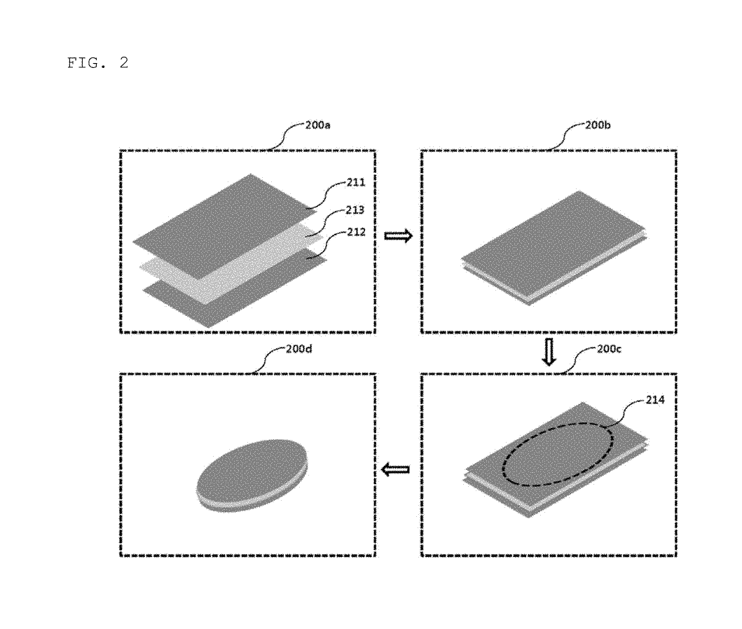

FIG. 2 is a schematic process diagram illustrating a method of manufacturing a nonconductive magnetic shielding block according to an embodiment of the present disclosure.

Referring to FIG. 2, as indicated by reference numeral 220a, the non-conductive magnetic shielding block may include a nonconductive magnetic shielding sheet 213 and a first cover tape 213 and a second cover tape 212 disposed on both sides of the non-conductive magnetic shielding sheet 213. Here, the first cover tape 211 and the second cover tape 212 may be PET-based double-sided adhesive tapes, and may function to fix the nonconductive magnetic shielding sheet 213, which is fragile to breakage.

As shown in a region indicated by reference numeral 200b, the nonconductive magnetic shielding sheet 213 and the first and second cover tapes 211 and 212 are bonded together. Thereafter, as shown in a region indicated by 200c, a cutting area 214 is marked on one side of the cover tapes, and then the marked cutting area 214 is cut off. Thereby, a nonconductive magnetic shielding block as indicated by reference numeral 200d may be acquired. While the cutting area is shown in the region indicated by reference numeral 200c of FIG. 2 as having a circular shape, this is merely an example. It should be noted that the shape and size of the cutting area 214 may vary depending on the shape and size of the reception coil.

Generally, the ferrite-based magnetic shielding member is easily broken and the magnetic permeability thereof may vary depending on the pattern and degree of breaking. The nonconductive magnetic shielding sheet 213 may be broken into a predetermined pattern so as to have a desired magnetic permeability, and the first and second cover tapes 211 and 212 are used to maintain the created pattern. Here, the first and second cover tapes 211 and 212 may have insulating properties. Hereinafter, for simplicity, the cover tape used in manufacture of a conductive magnetic shielding block is interchangeably referred to as an insulating cover tape.

The first and second cover tapes 211 and 212 are also used to make the nonconductive magnetic shielding block flexible. Accordingly, the nonconductive magnetic shielding block according to the present disclosure may have durability against external impact.

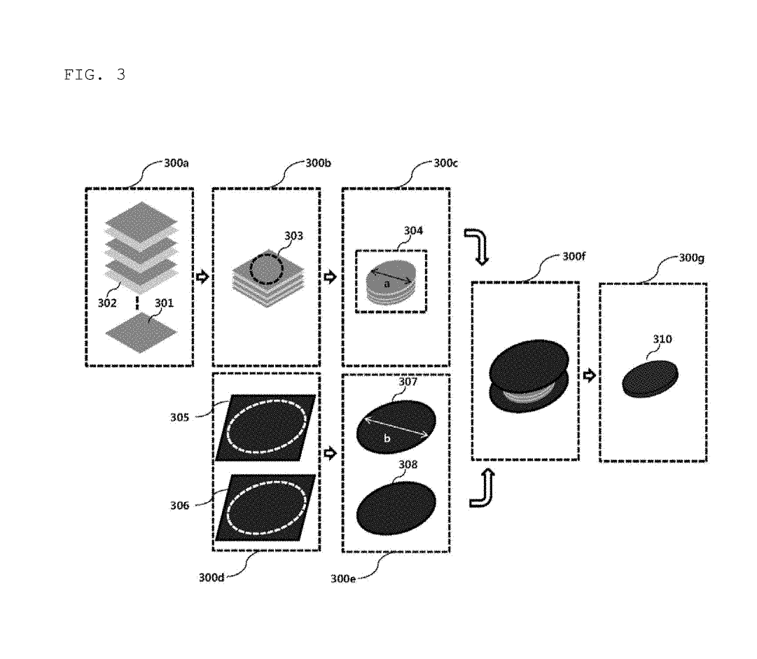

FIG. 3 is a process diagram illustrating a method of manufacturing a conductive magnetic shielding block according to an embodiment of the present disclosure.

As shown in regions indicated by reference numeral 300a and 300b in FIG. 3, n conductive magnetic shielding sheets 301 may be bonded to each other using n-1 intermediate adhesive members 302. Here, n may be a natural number greater than or equal to 2. The conductive magnetic shielding sheet according to an embodiment of the present disclosure may be a nanocrystal-based or amorphous-based sheet and may have a thickness of 17 μm to 25 μm. Therefore, it should be noted that, in order to obtain a desired magnetic permeability, the number of conductive magnetic shielding sheets included in the conductive magnetic shielding block may vary depending on the magnetic permeability required in the wireless charging system or the wireless power reception module.

Thereafter, as shown in the regions indicated by reference numerals 330b and 300c, a cutting area 303 may be marked on one surface of the bonded sheets, and the marked cutting area may be cut off. Here, marking and cutting of the cutting area may be performed manually or by a programmed robot. The shape and size of the cutting area may be determined according to the shape and size of the reception coil applied to the wireless power reception module.

Hereinafter, for simplicity, the conductive magnetic shielding member that is cut after the sheets are bonded through operations 300a to 300c will be referred to as a first block 304. Here, the diameter of the upper end surface and the lower end surface of the first block 304 may be a.

As shown in the regions indicated by reference numerals 300d and 300e, the first and second cover tape sheets 305 and 306 may be cut to acquire first and second cover tapes 307 and 308 having a diameter b.

Here, the diameter b of the cut cover tapes 307 and 308 is larger than the diameter a of the first block 304. In one example, the diameter b of the cut cover tapes 307 and 308 may be determined based on the diameter a of the first block 304 and the number n of conductive magnetic shielding sheets included in the conductive magnetic shielding block. That is, as the number of conductive magnetic shielding sheets increases, the diameter b of the cut cover tapes 307 and 308 may increase.

As shown in the region indicated by reference numeral 300f, the cut first and second cover tapes 307 and 308 may be attached to the upper end surface and lower end surface of the first block 304, respectively, and then the edges of the first and second cover tapes 307 and 308 may be pressed toward the cut surface of the first block 304. Thereby, an insulating magnetic shielding block 310 having the front surface of the first block 304 covered with a cover tape may be produced as shown in the region indicated by reference numeral 300g.

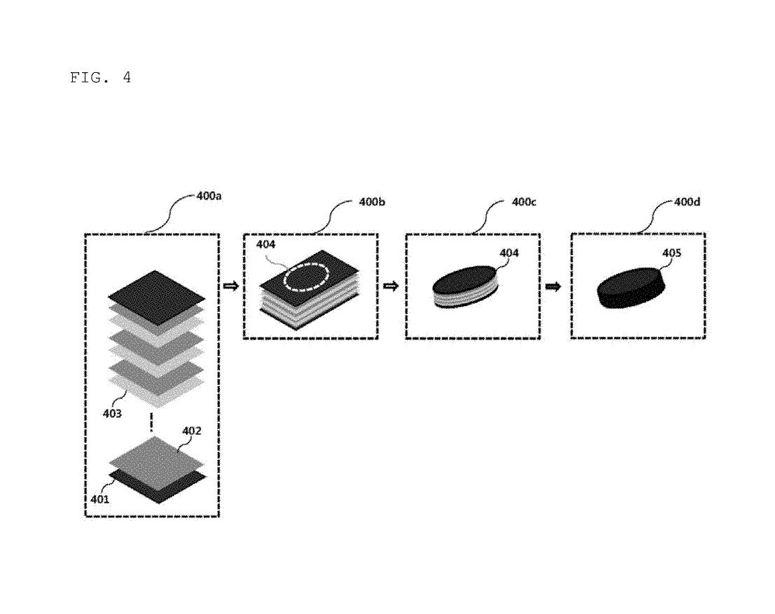

FIG. 4 is a process diagram illustrating a method of manufacturing a conductive magnetic shielding block according to another embodiment of the present disclosure.

Referring to the region indicated by reference numeral 400a in FIG. 4, n conductive magnetic shielding sheets 301 are disposed so as to be bonded to each other with n-1 intermediate adhesive members 302, and an insulating cover tape 401 may be attached to the outermost conductive magnetic shielding sheet.

After the n conductive magnetic shielding sheets 301 disposed in operation 400a are bonded to each other, the cutting area 404 shown in the region indicated by reference numeral 400b in FIG. 4 may be cut off. Thereby, a first block 405 as shown in the region indicated by reference numeral 400c may be produced. At this time, in order to insulate the cut surface of the first block 405, an insulating coating agent may be applied to the cut surface, and thus a conductive shielding block 406 whose entire surface is insulated may be produced, as shown in the region indicated by reference numeral 400d.

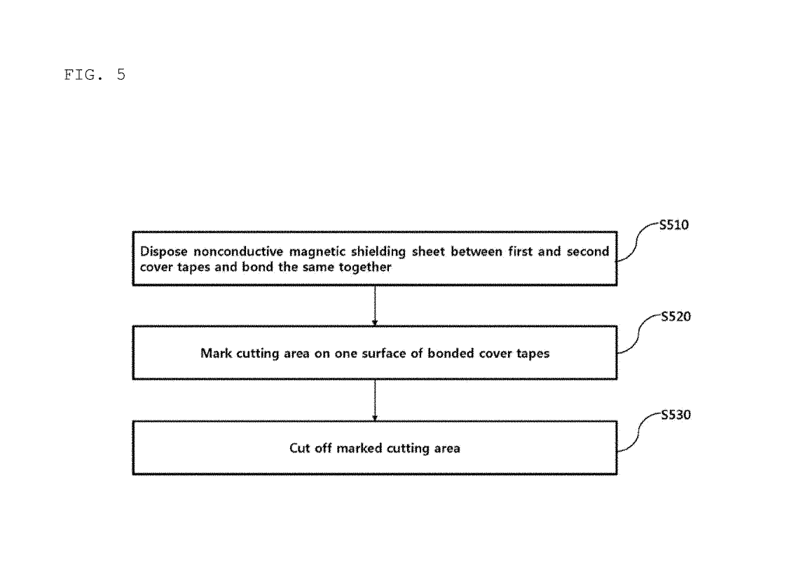

FIG. 5 is a flowchart illustrating a method of manufacturing a nonconductive magnetic shielding block according to an embodiment of the present disclosure.

Referring to FIG. 5, a method of manufacturing a nonconductive magnetic shielding block may include arranging a nonconductive magnetic shielding sheet between first and second cover tapes and bonding the same together (S510), marking a cutting area on one surface of the bonded cover tapes (S520), and cutting off the marked cutting area (S530). Here, the shape and size of the cutting area may correspond to the shape and size of the reception coil mounted on the wireless power reception module.

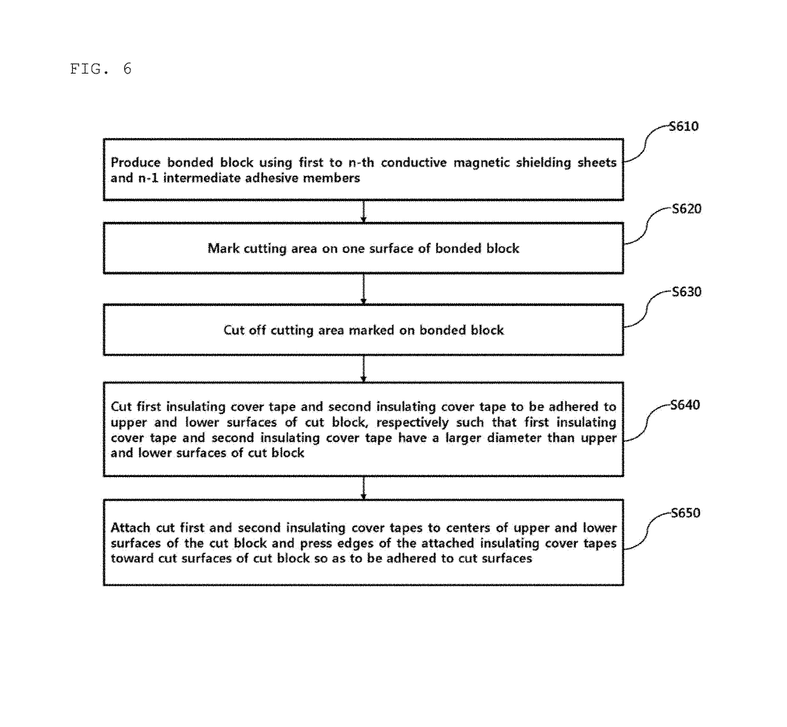

FIG. 6 is a flowchart illustrating a method of manufacturing a conductive magnetic shielding block according to an embodiment of the present disclosure.

Referring to FIG. 6, a method of manufacturing a conductive magnetic shielding block may include producing a bonded block using first to n-th conductive magnetic shielding sheets and n-1 intermediate adhesive members (S610), marking a cutting area on one surface of the bonded block (S620), cutting off the cutting area marked on the bonded block (S630), cutting first and second insulating cover tapes so as to have a diameter larger than a diameter of upper and lower surfaces of the cut bonded block, the first and second insulating cover tapes being attached to the upper and lower surfaces of the cut bonded block (S640), and attaching the cut first and second insulating cover tapes to a center of the upper and lower surfaces of the cut bonded block and pressing edges of the attached insulating cover tapes toward a cut surface of the cut bonded block so as to be bonded to the cut bonded block.

Here, the size of the cut first and second insulating cover tapes may be determined based on the size of the upper/lower surfaces of the bonded block and the number n of conductive magnetic shielding sheets included in the conductive magnetic shielding block.

Therefore, the conductive shielding block manufactured using the manufacturing method of the conductive magnetic shielding block of FIG. 6 has an excellent insulation property and high durability against corrosion because the surfaces are entirely insulated using the insulating cover tapes.

In addition, with the manufacturing method of the conductive magnetic shielding block of FIG. 6, the number of conductive magnetic shielding sheets included in the conductive shielding block may be easily changed according to the magnetic permeability required by the corresponding wireless charging system or wireless power reception module. Therefore, conductive shielding blocks having a variety of magnetic permeabilities may be produced.

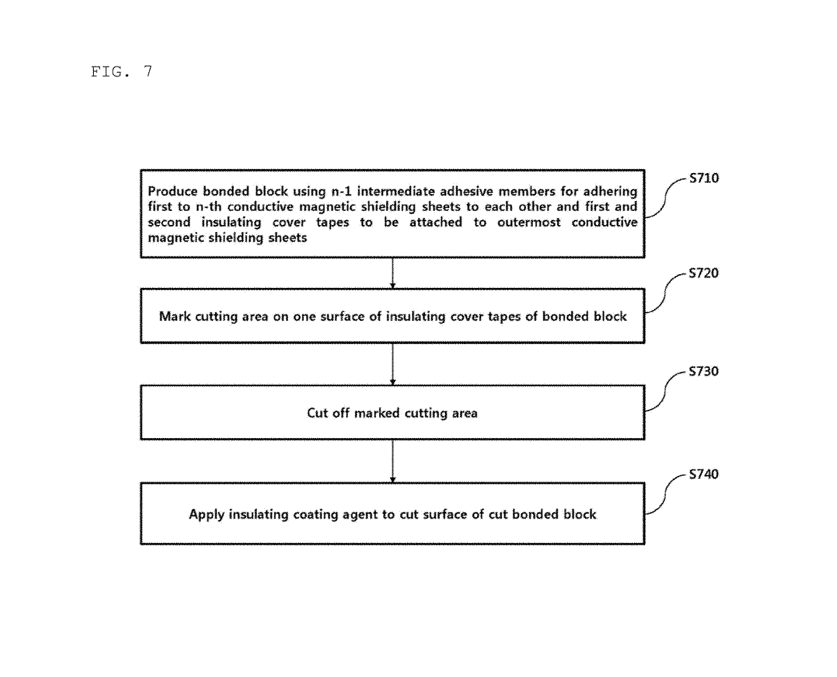

FIG. 7 is a flowchart illustrating a method of manufacturing a conductive magnetic shielding block according to another embodiment of the present disclosure.

Referring to FIG. 7, a method of manufacturing a conductive magnetic shielding block may include producing a bonded block using n-1 intermediate adhesive members for bonding first to n-th conductive magnetic shielding sheets to each other and first and second insulating cover tapes attached to each of the outermost conductive magnetic shielding sheets (S710), marking a cutting area on one surface of the insulating cover tapes of the bonded block (S720), cutting off the marked cutting area (S730), and applying an insulating coating agent to a cut surface of the cut bonded block (S740). Here, the outermost conductive magnetic shielding sheets mean the sheets arranged at the lowermost position and the uppermost position among the n laminated conductive magnetic shielding sheets.

Therefore, with the manufacturing method of the conductive magnetic shielding block of FIG. 7, the surfaces are entirely insulated using the insulating cover tapes and the insulating coating agent, and accordingly a conductive magnetic shielding block having excellent insulation and high durability against corrosion may be produced.

In addition, with the manufacturing method of the conductive magnetic shielding block of FIG. 7, the number of conductive magnetic shielding sheets included in the conductive shielding block may be easily changed according to the magnetic permeability required by the corresponding wireless charging system or wireless power reception module. Therefore, conductive shielding blocks having a variety of magnetic permeabilities may be produced.

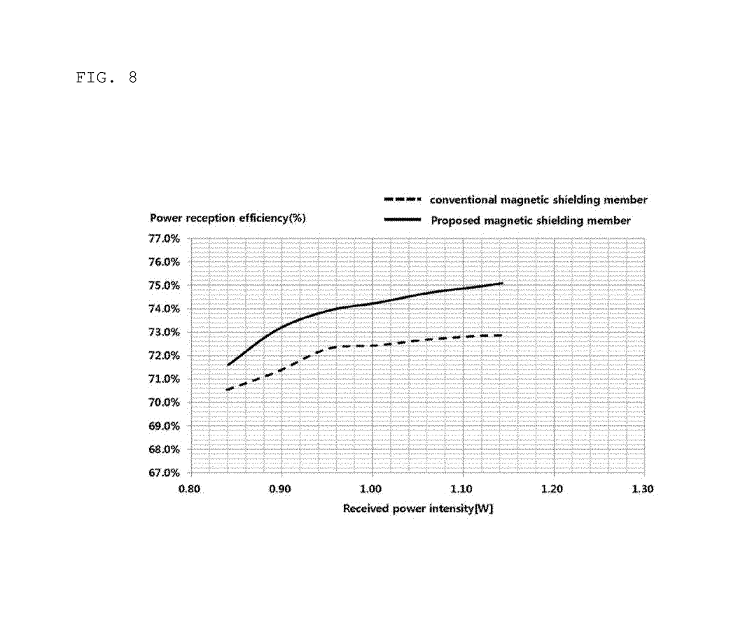

FIG. 8 is a graph depicting wireless power reception efficiency of a wireless power reception module using a magnetic shielding block manufactured according to embodiments of the present disclosure.

Specifically, FIG. 8 is a graph of experimentation results depicting changes in wireless power reception efficiency with respect to the intensity of the received power for a magnetic shielding member (conventional magnetic shielding member) used in the conventional wireless power reception module and a magnetic shielding member (proposed magnetic shielding member) according to the present disclosure.

FIG. 8 shows that the power reception efficiency of the wireless power receiver using the proposed magnetic shielding member is higher by 2% or more than that of the wireless power receiver using the conventional magnetic shielding member in a section where the received power is greater than or equal to 0.9 W.

It is apparent to those skilled in the art that the present disclosure may be embodied in specific forms other than those set forth herein without departing from the spirit and essential characteristics of the present disclosure.

Therefore, the above embodiments should be construed in all aspects as illustrative and not restrictive. The scope of the disclosure should be determined by the appended claims and their legal equivalents, and all changes coming within the meaning and equivalency range of the appended claims are intended to be embraced therein.

### INDUSTRIAL APPLICABILITY

A magnetic shielding block manufactured according to the present disclosure is applicable to a wireless charging device for which a magnetic shielding member having high shielding performance and high magnetic permeability is required.

1-20. (canceled)

21. A magnetic shielding block, comprising:
first and second cover tapes; and
a nonconductive magnetic shielding sheet disposed between the first cover tape and the second cover tape,
wherein the nonconductive magnetic shielding sheet is bonded with the first cover tape and the second cover tape, and
wherein the magnetic shielding block is formed by cutting off cutting areas marked on one surface of the bonded cover tapes.

22. The magnetic shielding block according to claim 21, wherein the nonconductive magnetic shielding sheet is formed of a ferrite-based material.

23. The magnetic shielding block according to claim 22, wherein the ferrite-based material is any one of a Ni—Zn—Cu-based material, a Ni—Zn-based material and a Mn—Zn-based material.

24. The magnetic shielding block according to claim 21, wherein the cutting area is circular and a diameter of the cutting area is 30 mm less than or equal to 30 mm.

25. The magnetic shielding block according to claim 21, wherein a magnetic permeability of the nonconductive magnetic shielding sheet has a real part less than or equal to 300 and an imaginary part less than or equal to 20 in a low frequency band below 300 KHz.

26. A magnetic shielding block, comprising:
first to n-th conductive magnetic shielding sheets, n>=2;
n-1 intermediate adhesive members disposed between two adjacent the conductive magnetic shielding sheets to produce a bonded block; and
a first insulating cover tape and a second insulating cover tape to be adhered to upper and lower surfaces of the bonded block, respectively,
wherein a portion of the bonded block is cut off, and
wherein the first insulating cover tape is adhered to the upper surface of the cutoff bonded block and the second insulating cover tape is adhered to the lower surface of the cutoff bonded block.

27. The magnetic shielding block according to claim 26, wherein cut surface of the cutoff bonded block is fully covered with the first insulating cover tape and the second insulating cover tape.

28. The magnetic shielding block according to claim 27, wherein the bonded block is cut into a circle, and
wherein the adhered first insulating cover tape and the second insulating cover tape are cut into a diameter corresponding to area of the cut surface.

29. The magnetic shielding block according to claim 26, wherein the conductive magnetic shielding sheets are formed of any one of a nano-crystal-based material and an amorphous-based material.

30. The magnetic shielding block according to claim 26, wherein the conductive magnetic shielding sheets have a thickness of 17 micrometers (μm) to 25 μm.

31. The magnetic shielding block according to claim 26, wherein the magnetic shielding block is used in a wireless power receiver and has a diameter of 30 mm or less.

32. A wireless power reception device comprising:
a reception coil configured to wirelessly receive alternating current (AC) power;
a control circuit board connected to both terminals of the reception coil;
a magnetic shielding member mounted between the reception coil and the control circuit board to block the received AC power from being transferred to the control circuit board; and
an adhesive member configured to adhere the magnetic shielding member and the reception coil to each other.

33. The wireless power reception device according to claim 32, wherein the reception coil is any one of a patterned coil and a wire-wound coil.

34. The wireless power reception device according to claim 33, wherein the patterned coil is mounted as the reception coil when a diameter of the reception coil exceeds 25 mm, and the wire-wound coil is mounted as the reception coil when the diameter of the reception coil is greater than or equal 25 mm.

35. The wireless power reception device according to claim 31, wherein the magnetic shielding member is a conductive magnetic shielding member formed of any one of a nano-crystal-based material and an amorphous-based material.

36. The wireless power reception device according to claim 32, wherein the magnetic shielding member is a nonconductive magnetic shielding member formed of any one of a Ni—Zn-Cu-based material, a Ni—Zn-based material, and a Mn—Zn-based material.

37. The wireless power reception device according to claim 36, wherein a magnetic permeability of the nonconductive magnetic shielding member has a real part less than or equal to 300 and an imaginary part less than or equal to 20 in a low frequency band below 300 KHz.

38. The wireless power reception device according to claim 32, wherein the magnetic shielding member comprises:
first to n-th conductive magnetic shielding sheets; and
n-1 intermediate adhesive members configured to adhering the first to n-th conductive magnetic shielding sheets to each other,
wherein the first to the n-th conductive magnetic shielding sheets adhered to each other are cut to a size of the reception coil and then subjected to surface insulation treatment.

39. The wireless power reception device according to claim 38, wherein the surface insulation treatment is performed using at least one of an insulating cover tape or an insulating coating agent.

40. The wireless power reception device according to claim 39, wherein the surface insulation treatment is performed by applying the insulating coating agent to the cut surface.
